(19) United States
(12) Patent Application Publication
(10) Pub. No.: US 2018/0062006 A1
(43) Pub. Date: Mar. 1, 2018

(54) CONDUCTIVE PASTE COMPOSITION FOR FRONT ELECTRODE OF SOLAR CELL AND SOLAR CELL USING THE SAME

(71) Applicant: KOREA ELECTRONICS TECHNOLOGY INSTITUTE, Seongnam-si (KR)

(72) Inventors: Sung Hyun KIM, Yongin-si (KR); Myong Jae YOO, Seoul (KR); Ji Sun PARK, Seongnam-si (KR)

(21) Appl. No.: 15/447,077

(22) Filed: Mar. 1, 2017

(30) Foreign Application Priority Data
Aug. 25, 2016 (KR) 10-2016-0108244

(51) Int. Cl. H01L 31/0224; H01L 31/0236; H01L 31/0216

(52) U.S. Cl. CPC H01L 31/022425; H01L 31/02168; H01L 31/02363

(57) ABSTRACT

Disclosed is a conductive paste for a front electrode of a solar cell, including copper-silver core-shell particles, boron, and a binder, wherein the boron is contained in an amount of 2.5 to 11 wt % based on the total weight of the conductive paste.

### CROSS-REFERENCE TO RELATED APPLICATION

This application claims the benefit of Korean Patent Application No. 10-2016-0108244, filed Aug. 25, 2016, entitled “Conductive paste composition for front electrode of solar cell and solar cell using thereof”, which is hereby incorporated by reference in its entirety into this application.

### BACKGROUND OF THE INVENTION

### 1. Technical Field

The present invention relates to a conductive paste composition for a front electrode of a solar cell and a solar cell using the same, and more particularly to a conductive paste composition, which includes copper-silver core-shell particles and boron.

### 2. Description of the Related Art

A solar cell is typically composed of a p-n junction structure, and is configured so as to include an antireflective layer for efficiently absorbing light to the inside of a solar cell, and a front electrode and a back electrode, which enable electron-hole pairs formed within silicon to be extracted to the outside.

A front electrode functions to ensure solar cell efficiency and plays an important role in a module for connecting multiple solar cells. When light is incident on a solar cell, it may interact with the material for a semiconductor of the solar cell, and thus negatively charged electrons escape from the material to create positively charged holes, whereby current is allowed to flow through the movement thereof, which is called a photoelectric effect. The front electrode collects the generated electrons without loss to thus form an electrical path.

When an electrode for a solar cell is manufactured, it is famed at the position on which an antireflective layer is formed. The electrode is typically fabricated in a manner in which a paste, composed of a conductive powder such as silver powder, glass frit, a resin binder, and an additive, as necessary, is applied on an antireflective layer and then fired.

In order to improve the power-generation characteristics of a solar cell, the properties of electrodes are regarded as important. For example, when the series resistance of the electrode is decreased, current loss may be reduced, thus increasing power-generation efficiency. To this end, a variety of techniques have been devised.

A front electrode for use in a conventional crystalline silicon solar cell is mainly formed of a silver paste. However, many attempts have been made to prepare a paste by minimizing the silver content in the paste to reduce cell costs due to the increasing price of silver.

In order to replace silver, techniques for forming an electrode having a Ni/Cu/Ag structure using a plating process are being developed. However, these techniques require the removal of an antireflective layer and are employed in pilot lines but have not been applied in mass production due to environmental problems such as wastewater generation, etc.

A CuP-based paste for use in a front electrode of a solar cell was prepared by Hitachi, but the resistivity thereof is not disclosed therein.

US20110315217A1 discloses a technique for manufacturing an electrode for a solar cell using copper-based particles or core-shell particles. Although this technique essentially needs high-temperature processing when the solar cell is fabricated, there is no disclosure regarding any solution for solving oxidation problems that occur during the high-temperature processing.

A resistivity of 3×10⁻⁵ was achieved By Napra (Japan) using a copper alloy and LMPA, but is only possible in a process at 300° C. or less, and is thus unsuitable for a high-temperature firing process at 800° C. or more. Since the resistivity is increased with an increase in the firing temperature, it is unknown whether a resistivity of 2×10⁻⁴, required of a front electrode, may be achieved upon high-temperature firing.

Also, Japanese Patent Application Publication No. 2005-243500 discloses a method of manufacturing a conductive electrode, wherein a conductive paste therefor is composed of an organic binder, a solvent, glass frit, a conductive powder, and at least one metal or metal compound selected from among Ti, Bi, Zn, Y, In and Mo, and the average particle size of the metal or metal compound ranges from of 0.001 μm to less than 0.1 μm, whereby high conductivity with a semiconductor and high adhesion may be imparted. However, the firing of the paste may suffer from problems in which contact resistance is increased due to film shrinkage or in which fine cracking is caused.

These problems may adversely affect the characteristics of solar cells. For example, the in-plane uniformity of solar cells may deteriorate, or the conversion efficiency of solar cells may decrease.

Furthermore, in order to reduce the use of expensive silver, a conductive paste using a silver-coated copper composite (e.g. copper-silver core-shell particles) is provided, but such a core-shell structure is problematic because the copper core is exposed while the silver coating layer agglomerates upon sintering. The exposed copper core is oxidized at its surface, and thus the resistivity thereof may increase, making it impossible to attain conductivity. Hence, the above paste is unsuitable for use in the manufacture of a front electrode of a solar cell, in lieu of a conventional silver paste.

### SUMMARY OF THE INVENTION

Accordingly, the present invention has been made keeping in mind the problems encountered in the related art, and the present invention is intended to provide a conductive paste for a front electrode of a solar cell, which may be used in lieu of an expensive silver paste and may remarkably decrease resistivity even upon high-temperature firing, and also to provide a front electrode of a solar cell including the same.

An aspect of the present invention provides a conductive paste for a front electrode of a solar cell, comprising copper-silver core-shell particles, boron, and a binder, wherein the boron is contained in an amount of 2.5 to 11 wt % based on the total weight of the conductive paste.

In an embodiment of the present invention, the copper-silver core-shell particles may be configured such that copper is coated with silver.

In an embodiment of the present invention, silver of the copper-silver core-shell particles may be used in an amount of 5 to 20 wt %.

In an embodiment of the present invention, the copper-silver core-shell particles may have a particle size D50 ranging from 0.5 μm to 10 μm.

In an embodiment of the present invention, the conductive paste may further include at least one selected from among a dispersant, a thixotropic agent, a defoamer, a plasticizer, a viscosity stabilizer, a pigment, a UV stabilizer, an antioxidant, a coupling agent, and combinations thereof.

Another aspect of the present invention provides a front electrode of a solar cell, comprising the aforementioned conductive paste.

Still another aspect of the present invention provides a solar cell, comprising the aforementioned conductive paste.

Yet another aspect of the present invention provides a solar cell, comprising the aforementioned front electrode.

According to the present invention, a front electrode composed mainly of copper-silver core-shell particles can be provided, and can thus replace a front electrode composed exclusively of silver, and can achieve low resistivity even in a high-temperature process for firing a conventional silver paste.

### BRIEF DESCRIPTION OF THE DRAWINGS

FIG. 1 shows front and back electrode structures of a typical crystalline silicon solar cell using a silver electrode; and

FIG. 2A is a cross-sectional image showing the paste containing no boron after high-temperature firing, and FIG. 2B is a cross-sectional image showing the paste containing boron after high-temperature firing.

### DESCRIPTION OF SPECIFIC EMBODIMENTS

An aspect of the present invention addresses a conductive paste for a front electrode of a solar cell, including copper-silver core-shell particles, boron, and a binder, wherein the boron is contained in an amount of 2.5 to 11 wt % based on the total weight of the conductive paste.

Preparation of Conductive Paste for Front Electrode of Solar Cell

In the preparation of a conductive paste, a metal powder may be added with an organic binder, an organic solvent, etc. so that the metal powder becomes viscous and may be subjected to screen printing.

Copper-silver core-shell particles are configured such that copper is coated with silver, wherein silver is applied on more than half of the surface of the copper.

The copper for the copper-silver core-shell particles may include copper, copper oxide, a copper alloy, a copper compound, or a powder material that enables the precipitation of copper through firing, which may be used alone or in a combination of two or more.

The silver for the copper-silver core-shell particles may include silver, silver oxide, a silver alloy, a silver compound, or a powder material that enables the precipitation of silver through firing, which may be used alone or in a combination of two or more.

Any coating process for forming the copper-silver core-shell particles may be used without particular limitation, so long as it is able to form a core-shell structure in which the copper component is coated with the silver component. The amount of silver in the copper-silver core-shell particles is not particularly limited, but may fall in the range of 5 to 20 wt %. If the amount of silver exceeds 20 wt %, the economic benefit obtained by replacing silver may become insufficient. On the other hand, if the amount thereof is less than 5 wt %, the reduction in resistivity is limited.

The copper-silver core-shell particles have a particle size D50 ranging from 0.5 μm to 10 μm. For example, D50 of 2 to 4 μm may be applied, but the present invention is not limited thereto. If the particle size D50 is less than 0.5 μm, the particles are excessively small and a bulk state thereof may result, making it unsuitable to form a paste. On the other hand, if the particle size D50 exceeds 10 μm, it is difficult to realize a fine line width.

The present inventors have discovered that the use of copper-silver core-shell particles alone results in excessively high resistivity, but the addition of boron in a predetermined amount may surprisingly decrease resistivity.

The conductive paste of the present invention is able to achieve a very low resistivity of 3.2×10⁻³ or less even upon firing at 800° C. or more.

Boron is deemed to suppress oxidation upon high-temperature firing of a front electrode to thus prevent the resistivity of the copper-silver core-shell particles from increasing.

Boron may be provided in the form of an oxide, and boron oxide may include all oxidized forms of boron without particular limitation as to the oxidation numbers of boron. Examples of boron oxide may include B₂O₃, B₂O, and B₆O. These boron oxides may be used alone or in combinations of two or more thereof. Particularly useful as the boron oxide is B₂O₃.

Boron is used in an amount of 2.5 to 11 wt % based on the total weight of the conductive paste. If the amount of boron is less than 2.5 wt %, the effect of suppressing oxidation may become insignificant, making it difficult to decrease resistivity. On the other hand, if the amount thereof exceeds wt %, resistivity may be somewhat increased. When the amount of boron is greater than 11 wt %, boron itself may cause oxidation, and thus resistivity may be increased again. In the case where the use of boron having a large specific surface area is increased, it is difficult to knead the paste.

In the present invention, any resin binder may be used for the conductive paste for a front electrode of a solar cell, and may include a cellulose-based resin, polyvinyl alcohol, an acrylic resin, a butyral resin, a castor oil fatty acid modified alkyl resin, an epoxy resin, a phenol resin, a rosin ester resin, polymethacrylate, and ethylene glycol monobutyl ether monoacetate. Particularly useful is a cellulose-based resin or an acrylic resin.

In the present invention, a solvent including no polymer, for example, water or an organic solvent may be used as a viscosity controller. Examples thereof may include hexane, cyclohexane, cycloether, amide, ketone, terpene, polyhydric alcohol ester, alcohol, and alcohol ester solvents. Particularly useful is dihydro-terpinyl acetate, terpinol, or butyl ketyl acetone.

The amount of the resin binder is 15 wt % or less based on the total weight of the paste. If the amount thereof exceeds wt %, viscosity may decrease, and thus printability may become problematic. The amount of the binder has to be determined within a range that causes no problems not only in terms of viscosity and printability but also in terms of the kneading of a paste and mixing with a filler and a vehicle.

The conductive paste of the present invention may include at least one additive selected from among a thickener, a stabilizer, a dispersant, a thixotropic agent, a defoamer, a plasticizer, a viscosity controller, a pigment, a UV stabilizer, an antioxidant, a coupling agent, and combinations thereof. The amount of the additive may be determined depending on the properties of the final conductive paste. The amount of the additive may be appropriately determined by those skilled in the art.

The conductive paste of the present invention may be applied on a desired portion of the surface of a solar cell through screen printing. Here, this paste has to possess a predetermined viscosity when the above printing process is used.

As mentioned above, the conductive paste of the present invention is used to form an electrode composed mainly of copper-silver core-shell particles, which may be positioned on the light-receiving surface of a solar cell. The conductive paste of the present invention is printed and dried on the light-receiving surface of a solar cell. Separately, a back electrode made of aluminum or silver may be formed on the remaining surface of the solar cell.

Fabrication of Front Electrode of Solar Cell

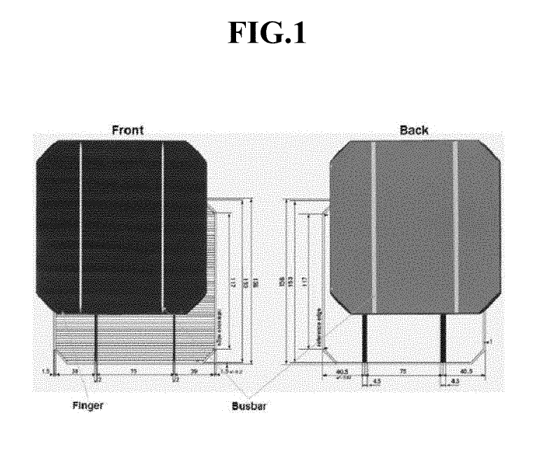

FIG. 1 shows front and back electrode structures of a typical crystalline silicon solar cell using a silver electrode. Here, the front electrode includes a finger electrode for collecting electrons and a busbar electrode that enables series/parallel connection between cells. The back electrode is formed of aluminum and includes the same busbar electrode as the front electrode.

A solar cell of the present invention may include a monocrystalline silicon wafer or a polycrystalline silicon wafer, or may include a thin-film silicon wafer. The monocrystalline silicon wafer may be formed through a Czochralski process, and the polycrystalline silicon wafer may be formed through a casting process.

A silicon ingot formed through a Czochralski process or a casting process is sliced to a predetermined thickness, after which the surface thereof is etched with NaOH, KOH or fluoric acid and thus cleaned.

When a p-type silicon wafer is used, an n layer may be formed through diffusion of a pentavalent element such as phosphorus, and the depth of the diffusion layer may be variously adjusted depending on the diffusion temperature, time and the like.

An antireflective layer may be formed on the n layer. The antireflective layer is responsible for decreasing the reflectance of incident light from the surface of a solar cell in order to increase light absorption, thereby increasing the generation of current.

The antireflective layer may be provided in the form of a single layer or multiple layers using SiNx, TiO₂, SiO₂, MgO, ITO, SnO₂, or ZnO. The antireflective layer may be formed through a thin-film deposition process, such as sputtering, CVD (Chemical Vapor Deposition), etc.

Provided on the antireflective layer may be a front electrode using the conductive paste of the present invention.

The conductive paste of the present invention is subjected to screen printing in a predetermined pattern, dried using an IR oven, and fired so that it is connected to the n layer through the antireflective layer. Thereby, a front electrode of a solar cell may be manufactured.

Fabrication of Solar Cell

A solar cell is manufactured using the conductive paste for a front electrode. Specifically, the front surface of a wafer is subjected to texturing, formed with an N layer, further formed with an antireflective layer, screen-printed with the conductive paste in a predetermine pattern, and then dried in an IR oven. Thereafter, the back surface of the wafer is printed with an aluminum paste or the like and then dried in the same manner. The cell thus formed is fired at 800° C. or more for 3 to 5 sec in a firing furnace, thereby manufacturing a desired cell.

### EXAMPLES

### Examples 1 to 3 and Comparative Examples 1 to 4: Preparation of Conductive Paste

Copper-silver core-shell particles having a particle size D50 of 2 to 4 μm were used.

Pastes 1 to 7 were prepared using copper-silver core-shell particles (silver 9%, TCSP-0510), a boron powder (B95-1617, boron, purity 95 to 97%), and a binder (resin: ethyl cellulose, solvent: butyl carbitol, 1-dodecanol) in the amounts shown in Table 1 below.

TABLE 1

| | Ex. 1 | Ex. 2 | Ex. 3 | C. Ex. 1 | C. Ex. 2 | C. Ex. 3 | C. Ex. 4 |
|---|---|---|---|---|---|---|---|
| Paste No. | Paste 1 | Paste 2 | Paste 3 | Paste 4 | Paste 5 | Paste 6 | Paste 7 |
| Cu—Ag | 82.5 wt % | 78 wt % | 70 wt % | 85 wt % | 61 wt % | 54 wt % | 87 wt % |
| core-shell particles | | | | | | | |
| (Ag % 9) | | | | | | | |
| Boron | 2.5 wt % | 6 wt % | 11 wt % | 1.5 wt % | 14 wt % | 17 wt % | — |
| Binder | 15 wt % | 16 wt % | 9 wt % | 13.5 wt % | 25 wt % | 28 wt % | 13 wt % |
| Resistivity (Ω · cm) | 6.4 × 10⁻⁶ | 1.59 × 10⁻⁵ | 3.2 × 10⁻⁵ | 4.3 × 10⁻⁵ | 6.6 × 10⁻⁵ | 7.3 × 10⁻⁴ | —^{a} |

—^{a} indicates that resistivity could not be measured.

The binder was prepared by mixing ethyl cellulose N300 and ethyl cellulose N22 at a ratio of 3.76:7.52 with a solvent mixture comprising butyl carbitol and 1-dodecanol at a ratio of 53:35, followed by subjecting the resulting mixture to stirring for three days and aging for one day so as to remove foam therefrom.

The binder thus prepared was mixed with copper-silver core-shell particles and boron and pre-dispersed. Then, a 3-roll mill was utilized, in which the interval between rolls was adjusted, and a dispersion process was repeated five times, thus obtaining a paste, which was then aged at room temperature for one day, followed by printing and refrigerated storage at 4° C. for 60 days.

The paste thus obtained was applied on a silicon wafer using a screen through a thick film process, thermally treated in an ambient atmosphere, and measured for resistivity. The thermal treatment temperature was the same as in the typical sintering conditions using a silver paste for a solar cell, and firing was performed at 800 to 900° C. Since the resistivity of the electrode is increased due to the oxidation or the formation of a compound with an increase in the temperature, it is required to achieve a predetermined level or less.

Resistivity Measurement

The surface resistance of an electrode was measured using a 4-point probe, and the thickness of the same electrode was measured and multiplied by the surface resistance to calculate resistivity. The surface resistance measurement was performed using a LORESTA-GP/MCP-T610 surface resistance meter, available from Mitsubishi Chemical, and the electrode thickness measurement was performed using a DIGIMICRO MF 501 thickness gauge, available from Nikon Metrology.

The results of measurement of resistivity of Pastes 1 to 7 are shown in Table 1. As is apparent from Table 1, the resistivity of the pastes containing 2.5 to 11 wt % of boron fell in the range from 6.4×10⁻⁶ to 3.2×10⁻⁵. The paste for a front electrode of a solar cell is required to exhibit as low electrode resistivity as possible, and particularly 2.0×10⁻⁴ or less. Pastes 1 to 3 exhibited resistivity values of 6.4×10⁻⁶, 1.59×10⁻⁵ and 3.2×10⁻⁵, respectively, which are evaluated to be very superior. However, in the pastes containing boron in an amount greater than 11 wt % or less than 2.5 wt %, the resistivity was high, to the level of 4.3×10⁻⁵ to 7.3×10⁻⁴. In addition to the resistivity problem, furthermore, if the amount of boron exceeded 11 wt %, boron was not provided in ink form but was present in a powder phase upon mixing due to the large specific surface area thereof, and fine line widths were broken.

Meanwhile, Paste 7, containing no boron, exhibited high resistivity beyond the measurement range and was thus unsuitable for use in a front electrode of a solar cell. This is considered to be because the flow of electrons is hindered due to oxidation upon high-temperature firing of the front electrode, and thus resistivity falls out of the measurement range. In the present invention, when boron was added in an amount of 2.5 to 11 wt %, boron was able to suppress the oxidation of copper to thus achieve low resistivity and improve printability. As shown in the drawings, Paste 2, containing boron, can be seen to prevent the copper core from being oxidized after firing.

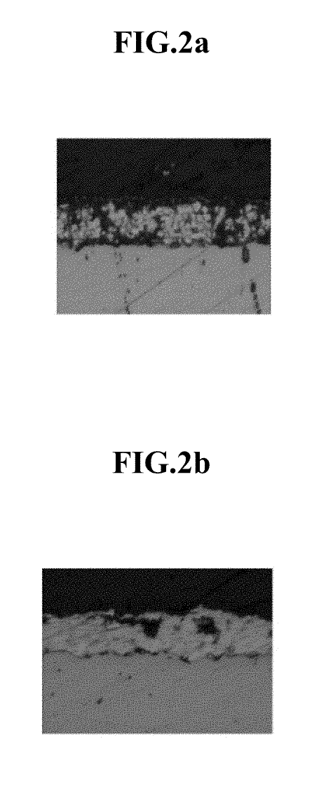

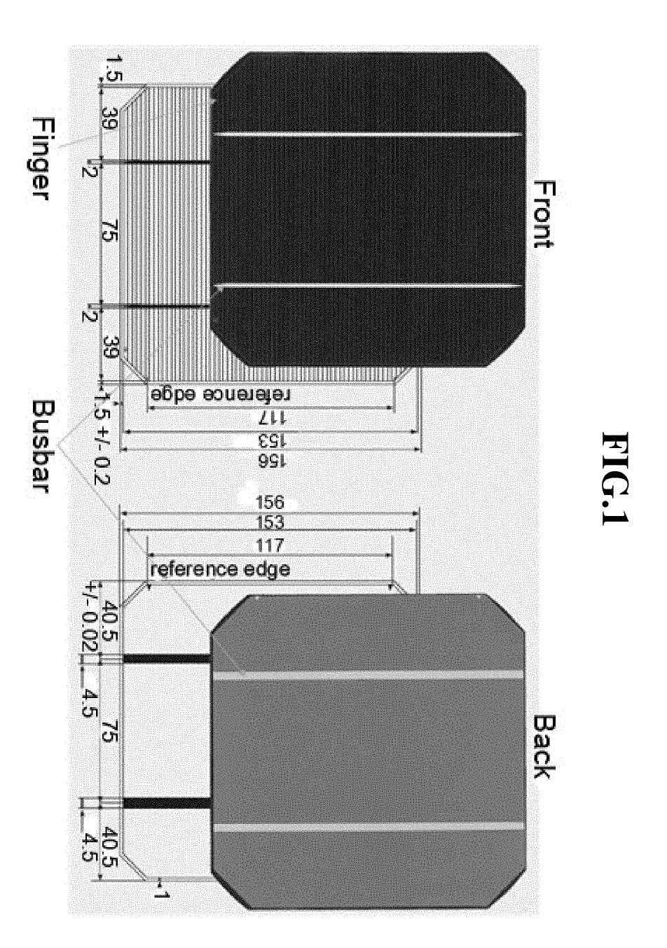

Specifically, FIG. 2A shows the cross-sectional image of the electrode after high-temperature firing using Paste 7 containing no boron, and FIG. 2B shows the cross-sectional image of the electrode after high-temperature firing using Paste 2 containing boron. In FIG. 2A, the paste containing no boron appeared black due to the oxidation of copper, and thus the electron transfer was considered to be hindered somewhat by the copper oxide CuₓO. Meanwhile, in FIG. 2B, the paste containing boron was formed into a bulk electrode without oxidation of copper, thus exhibiting low resistivity. This is deemed to be because the silver in the copper-silver core-shell particles has a melting point lower than that of copper, and thus the surface oxidation of copper is somewhat limited and necking of copper particles is easier, thus forming a bulk electrode.

### Comparative Examples 5 to 8: Paste Before Addition of Boron

As shown in Table 2 below, CuP alloy-based pastes containing silver were fired at 500° C. and 850° C., and the resistivity thereof was measured. The CuP alloys were purchased from Pometon.

As is apparent from the results of Table 2, the CuP alloy-based pastes containing silver without the addition of boron were reduced in resistivity with an increase in the amount of silver at firing temperatures of both 500° C. and 850° C. This is considered to be because silver functions as a main component of the electrode, and thus resistance is decreased. In the pastes containing the same amount of silver, the resistivity was worse at 850° C. than at 500° C. In the case where the silver was contained in a small amount, resistivity values varied greatly depending on the firing temperature. For example, when 27 wt % of silver was contained, the resistivity was 2.46×10⁻³ at 500° C. and was 1.83×10⁴ at 850° C. In this way, the resistivity was increased 0.74×10⁷ times with an increase in the firing temperature.

The resistivity values of the paste comprising only CuP without the addition of boron (Comparative Example 8) and the CuP pastes containing Ag (Comparative Examples 5 to 7) after firing were not low enough to be used for solar cell electrodes. Here, the resistivity of Comparative Example 5 was 7.1×10⁻⁵, which was the lowest among the above Comparative Examples, but was higher than 3.2×10⁻⁵, corresponding to the resistivity of the present invention.

Also, the amount of silver in Comparative Example 5 was 67 wt %. Consequently, in the CuP alloy-based pastes, even when silver was added, no paste satisfied the resistivity of 2.0×10⁻⁴, required in the art upon high-temperature firing at 850° C. Moreover, since silver was contained in an excessive amount of 67 wt %, no economic benefits can be obtained by replacing silver.

TABLE 2

| | | Composition (wt %) | | |
|---|---|---|---|---|
| | | CuP | | |
| | | Ag | Firing | Resistivity |
| | Paste | Binder | conditions | (Ω · cm) |
| C. Ex. 5 | CuP + Ag | 20 wt % | 500° C. | 7.1 × 10⁻⁵ |
| | | 67 wt % | 850° C. | 4.5 × 10⁻⁴ |
| | | 13 wt % | | |
| C. Ex. 6 | CuP + Ag | 40 wt % | 500° C. | 4.1 × 10⁻⁴ |
| | | 47 wt % | 850° C. | 1 × 10⁻³ |
| | | 13 wt % | | |
| C. Ex. 7 | CuP + Ag | 60 wt % | 500° C. | 2.46 × 10⁻³ |
| | | 27 wt % | 850° C. | 1.83 × 10⁴ |
| | | 13 wt % | | |
| C. Ex. 8 | CuP | 87 wt % | 500° C. | 1.12 × 10³ |
| | | 0 wt % | 850° C. | —^{a} |
| | | 13 wt % | | |

—^{a} indicates that resistivity could not be measured.

### Comparative Examples 9 to 16: Paste after Addition of Boron

CuP alloy-based pastes containing boron as shown in Table 3 below were fired, and the resistivity thereof was measured. The CuP alloys were purchased from Pometon (Comparative Examples 9 to 12) and from Pungsan (Comparative Examples 13 to 16).

In the CuP alloy-based pastes, when boron was added, the resistivity was reduced compared to when boron was not added, but no paste satisfied 3.2×10⁻⁵, corresponding to the resistivity of the present invention. The paste of Comparative Example 13 exhibited the lowest resistivity, namely 6.24×10⁻³, which was higher than that of the present invention. Consequently, the boron added to the paste manifested different resistivity reduction effects depending on the kind of metal.

TABLE 3

| | | Composition (wt %) | |
|---|---|---|---|
| | | CuP | |
| | | Boron | |
| | Paste | Binder | Resistivity |
| C. Ex. 9 | CuP | 67.82 wt % | 3.08 × 10⁻⁰¹ |
| | | 5.35 wt % | |
| | | 26.83 wt % | |
| C. Ex. 10 | CuP | 62.30 wt % | 3.44 × 10⁻⁰¹ |
| | | 9.84 wt % | |
| | | 27.87 wt % | |
| C. Ex. 11 | CuP | 55.07 wt % | —^{a} |
| | | 13.04 wt % | |
| | | 31.88 wt % | |
| C. Ex. 12 | CuP | 50.67 wt % | —^{a} |
| | | 16.00 wt % | |
| | | 33.33 wt % | |
| C. Ex. 13 | CuP | 67.82 wt % | 6.24 × 10⁻⁰³ |
| | | 5.35 wt % | |
| | | 26.83 wt % | |
| C. Ex. 14 | CuP | 62.30 wt % | 1.14 × 10⁻⁰¹ |
| | | 9.84 wt % | |
| | | 27.87 wt % | |
| C. Ex. 15 | CuP | 55.07 wt % | —^{a} |
| | | 13.04 wt % | |
| | | 31.88 wt % | |
| C. Ex. 16 | CuP | 50.67 wt % | —^{a} |
| | | 16.00 wt % | |
| | | 33.33 wt % | |

—^{a} indicates that resistivity could not be measured.

Although the embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A conductive paste for a front electrode of a solar cell, comprising copper-silver core-shell particles, boron, and a binder, wherein the boron is contained in an amount of 2.5 to 11 wt % based on a total weight of the conductive paste.

2. The conductive paste of claim 1, wherein the copper-silver core-shell particles are configured such that copper is coated with silver.

3. The conductive paste of claim 1, wherein silver of the copper-silver core-shell particles is used in an amount of 5 to 20 wt %.

4. The conductive paste of claim 1, wherein the copper-silver core-shell particles have a particle size D50 ranging from 0.5 μm to 10 μm.

5. The conductive paste of claim 1, further comprising at least one selected from among a dispersant, a thixotropic agent, a defoamer, a plasticizer, a viscosity stabilizer, a pigment, a UV stabilizer, an antioxidant, a coupling agent, and combinations thereof.

6. A front electrode of a solar cell, comprising the conductive paste of claim 1.

7. A solar cell, comprising the conductive paste claim 1.

8. A solar cell, comprising the front electrode of claim 6.
